(19) United States
(12) Patent Application Publication
(10) Pub. No.: US 2015/0340464 A1
(43) Pub. Date: Nov. 26, 2015

(54) SEMICONDUCTOR DEVICE AND MANUFACTURING METHOD THEREOF

(71) Applicant: Institute of Microelectronics, Chinese Academy of Sciences, Beijing (CN)

(72) Inventors: Zhaoyun TANG, Beijing (CN); Jiang YAN, Beijing (CN)

(21) Appl. No.: 14/814,003

(22) Filed: Jul. 30, 2015

Related U.S. Application Data
(63) Continuation of application No. PCT/CN2013/074878, filed on Apr. 27, 2013.

(30) Foreign Application Priority Data
Feb. 26, 2013 (CN) 201310059403.9

(51) Int. Cl. H01L 29/66; H01L 21/02; H01L 29/06; H01L 21/265; H01L 29/78; H01L 29/423

(52) U.S. Cl. CPC H01L 29/66621; H01L 29/66545; H01L 29/66553; H01L 29/78; H01L 29/4236; H01L 29/0649; H01L 21/26513; H01L 21/02233; H01L 21/02255

(57) ABSTRACT

A semiconductor device manufacturing method includes forming a gate opening in a semiconductor layer; forming a sacrificial gate in the gate opening; forming a source region and a drain region in the semiconductor layer in proximity to the gate opening; removing the sacrificial gate; and forming a gate stack comprising a replacement gate dielectric layer and a replacement gate conductor layer in the gate opening, wherein the gate opening is configured to define a thickness of a portion of the semiconductor layer for a channel region. Channel control in semiconductor devices formed according to the above method can be effectively improved.

This application is a National Phase application of, and claims priority to, PCT Application No. PCT/CN2013/074878, filed on Apr. 27, 2013, entitled SEMICONDUCTOR DEVICE AND MANUFACTURING METHOD THEREOF, which claimed priority to Chinese Application No. 201310059403.9, filed on Feb. 26, 2013. Both the PCT Application and Chinese Application are incorporated herein by reference in their entireties.

### TECHNICAL FIELD

The present disclosure relates to the field of semiconductors, and particularly to a method for manufacturing a semiconductor device using a gate last process and the semiconductors device obtained therefrom.

### BACKGROUND

A trend in development of integrated circuits is scaling down of transistors, which may lead to the well-known short-channel effect. Recently, ultra-thin-body SOI (UTB SOI) transistors have been proposed, in which a channel region in a top semiconductor layer of the UTB SOI wafer is completely depleted, thereby mitigating the short-channel effect effectively.

As shown in FIG. 20, a conventional UTB SOI transistor is formed on an SOI wafer, which comprises a bottom substrate 11, a buried insulating layer (BOX) 12, and a semiconductor layer 13. The UTB SOI transistor comprises a channel region formed in the semiconductor layer, a gate formed above the channel region, a spacer 16 formed on sidewalls of the gate, and raised source/drain (RSD) regions 17a and 17b. The gate comprises a gate dielectric layer 14 and a gate conductor layer 15.

In the UTB SOI transistor, the RSD reduces source/drain resistance and minimizes gate-source and gate-drain parasitic capacitance. In addition, when a silicide is formed above the source/drain region, the RSD can provide enough Si to participate in siliconization, so as to avoid depletion of Si in the source/drain regions in the siliconization process.

However, the manufacturing cost for the UTB SOI transistors is expensive due to the high cost of the UTB SOI wafer. Moreover, formation of the RSD involves pre-cleaning the semiconductor layer of the UTB SOI wafer and epitaxially growing a silicon layer thereon after forming the gate and the spacer on the sidewalls thereof. This makes the manufacturing process of the transistor complicated and results in a low product yield, which further increases the manufacturing cost.

### SUMMARY

The present disclosure provides, among other things, a semiconductor device that can improve channel control and a manufacturing method thereof.

According to one aspect of the disclosure, there is provided a method for manufacturing a semiconductor device is provided. The method comprises: forming a gate opening in a semiconductor layer; forming a sacrificial gate in the gate opening; forming a source region and a drain region in the semiconductor layer in proximity to the gate opening; removing the sacrificial gate; and forming a gate stack comprising a replacement gate dielectric layer and a replacement gate conductor layer in the gate opening, wherein the gate opening is configured to define a thickness of a portion of the semiconductor layer for a channel region.

According to another aspect of the disclosure, there is provided a semiconductor device. The semiconductor device comprises: a gate opening in a semiconductor layer; a gate stack comprising a replacement gate dielectric layer and a replacement gate conductor layer in the gate opening; and a source region and a drain region in the semiconductor layer in proximity to the gate opening, wherein the gate opening is configured to define a thickness of a portion of the semiconductor layer for a channel region.

The semiconductor device in accordance with the present disclosure can reduce the thickness of the channel region using the gate opening, whereby improving channel control. The gate opening defines a top surface of the channel region. In an optional embodiment, a well region is formed below the semiconductor layer using a dopant which has a type opposite to that in the source and drain regions to define a bottom surface of the channel region. The source and drain regions may have a relatively large thickness and small parasitic resistance because they are formed in the semiconductor layer in proximity to the gate opening. According to the present disclosure, it is not necessary to form the raised source and drain regions by a separate epitaxy process, thereby lowering down the manufacturing cost.

### BRIEF DESCRIPTION OF THE DRAWINGS

FIGS. 1-14 schematically show cross-sectional views of respective semiconductor structures at various stages for manufacturing a semiconductor device in accordance with a first embodiment of the method of the present disclosure, wherein each of the cross-sectional views is taken along a longitudinal direction of the channel;

FIGS. 15-17 schematically show cross-sectional views of respective semiconductor structures at some of various stages for manufacturing a semiconductor device in accordance with a second embodiment of the method of the present disclosure, wherein each of the cross-sectional views is taken along a longitudinal direction of the channel;

FIGS. 18-19 schematically show cross-sectional views of respective semiconductor structures at some of various stages for manufacturing a semiconductor device in accordance with a third embodiment of the method of the present disclosure, wherein each of the cross-sectional views is taken along a longitudinal direction of the channel; and

FIG. 20 is a structural diagram of a UTB SOI transistor in accordance with the prior art.

### DETAILED DESCRIPTION OF EMBODIMENTS

The present disclosure will be described herein in detail with reference to the drawings. In various drawings, like elements are represented by like reference signs. Various parts in the drawings are not drawn in scale for the sake of clearness and clarity.

For simplicity, a semiconductor structure that obtained through several steps may be drawn in a single drawing.

It should be appreciated that, when describing a structure of a device, a layer or a region being “on top of” or “above” another layer or another region means that, the layer or the region is directly on the top of the other layer or region, or there are further layers or regions therebetween. If the device is turned over, the layer or the region is “beneath” or “below” the other layer or region.

If the layer or the region is directly on the top of the other layer or region, an expression “to be directly on top of” or “to be directly on top of and adjoin” will be adopted.

In the present disclosure, the term “semiconductor structure” means a whole semiconductor structure formed in various steps for manufacturing a semiconductor device, including all layers or regions that have already been formed. The term “longitudinal direction of a channel region” means a direction from a source region to a drain region or an opposite direction thereof. The term “transverse direction of a channel region” means a direction that is perpendicular to the longitudinal direction of the channel region in a plane that is parallel to a main surface of the semiconductor substrate.

A lot of details of the disclosure are described herein, such as structure, material, size, and processing techniques of the device, so as to facilitate easy understanding of the disclosure. However, the disclosure can be implemented without such specific details, as can be understood by those skilled in the art.

Various portions of the semiconductor devices may be made of materials commonly known by those skilled in the art, unless otherwise specified below. The semiconductor materials may include, for example, III-V group semiconductors, such as GaAs, InP, GaN, and SiC, and IV group semiconductors, such as Si, and Ge. The gate conductor layer may be made of various conductive materials. For example, the gate conductor layer may be a metal layer, a doped polysilicon layer, a stacked gate conductor layer comprising a metal layer and a doped polysilicon layer, or a layer of other conductive material, such as any one selected from a group consisting of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni₃Si, Pt, Ru, Ir, Mo, HfRu, and RuOx, or any combination thereof. The gate dielectric layer may be made of SiO₂ or any material with a dielectric constant larger than that of SiO₂, for example, any one selected from a group consisting of oxide, nitride, oxynitride, silicate, aluminate, and titanate. The oxide may include, for example, any one selected from a group consisting of SiO₂, HfO₂, ZrO₂, Al₂O₃, TiO₂, and La₂O₃. The nitride may include, for example, Si₃N₄. The silicate may include, for example, HfSiOx. The aluminate may include, for example, LaAlO₃. The titanate may include, for example, SrTiO₃. The oxynitride may include, for example, SiON. Moreover, the gate dielectric layer may be made of not only materials known by those skilled in the art, but also materials that will be developed for gate dielectric in the future.

### First Embodiment

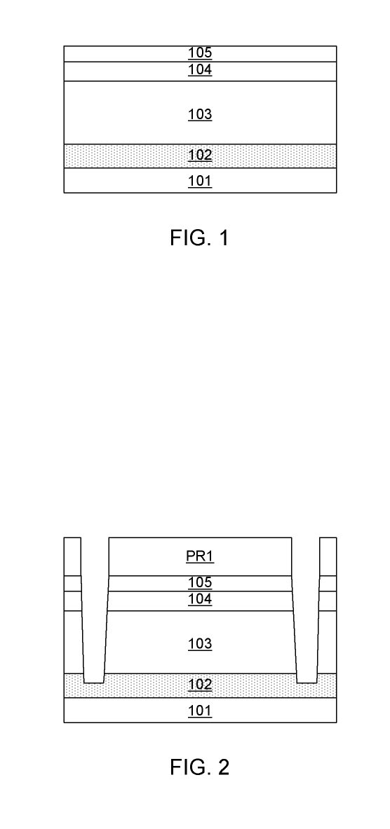

According to a first embodiment of the disclosure, a semiconductor device is manufactured as shown in FIGS. 1-14, which illustrate sectional views of respective semiconductor structures obtained in various stages.

As shown in FIG. 1, an initial semiconductor structure is for example an SOI (silicon on insulator) wafer. This SOI wafer includes a semiconductor substrate 101, a buried insulating layer 102, and a semiconductor layer 103. Unlike the UTB SOI transistor according to the prior art as shown in FIG. 20, a thickness (e.g., 25 nm-200 nm) of the semiconductor layer 103 of the SOI wafer used in the present disclosure may be larger than that (10 nm-15 nm) of the semiconductor layer of the UTB SOI wafer. Thus the present disclosure does not need to use the expensive UTB SOI wafers. In one example, the semiconductor substrate 101 and the semiconductor layer 103 of the SOI wafer are both made of, e.g., monocrystalline silicon, and the semiconductor layer 103 has a thickness of about 50 nm. The buried insulating layer 102 is for example made of silicon oxide, and has a thickness of about 140 nm.

A liner oxide layer 104 and a liner nitride layer 105 are successively formed on the semiconductor layer 103. The liner oxide layer 104 is for example made of silicon oxide with a thickness of about 2 nm-20 nm. The liner nitride layer 105 is for example made of silicon nitride with a thickness of about 50 nm-200 nm. The liner oxide layer 104 may alleviate stress between the semiconductor layer 103 and the liner nitride layer 105. The liner nitride layer 105 is used as a hard mask in a later etching step.

Processes for forming the above layers are known. For example, the liner oxide layer 104 may be formed through thermal oxidation and the liner nitride layer 105 may be formed through chemical vapor deposition.

Then, a photoresist layer PR1 is formed on the liner nitride layer 105 by spin coating The photoresist layer is etched by an etching process comprising exposing and developing steps to form a shallow-trench-isolation pattern. Exposed portions of the liner nitride layer 105 and the liner oxide layer 104 are successively removed from top to bottom with the photoresist layer as a mask through dry etching process, such as ion beam milling etching, plasma etching, reactive ion etching, or laser ablation, or through wet etching process in which etchant solution is used. The etching stops when reaching a surface of the semiconductor layer 103. The shallow-trench-isolation is formed in the liner nitride layer 105 and the liner oxide layer 104. The photoresist layer PR1 is removed by dissolving in solvent or incinerating.

The liner nitride layer 105 and the liner oxide layer 104 are used together as a hard mask to remove exposed portions of the semiconductor layer 103 by the above dry or wet etching process, so as to form shallow trenches in the semiconductor layer 103, as shown in FIG. 2. Although unnecessary, the buried insulating layer 102 and the semiconductor substrate 101 may be further etched according to the adopted etching processes, to allow the shallow trenches to extend to a predetermined depth in the buried insulating layer 102 or the semiconductor substrate 101. As can be understood by those skilled in the art, such shallow trenches surround an active region of the semiconductor device.

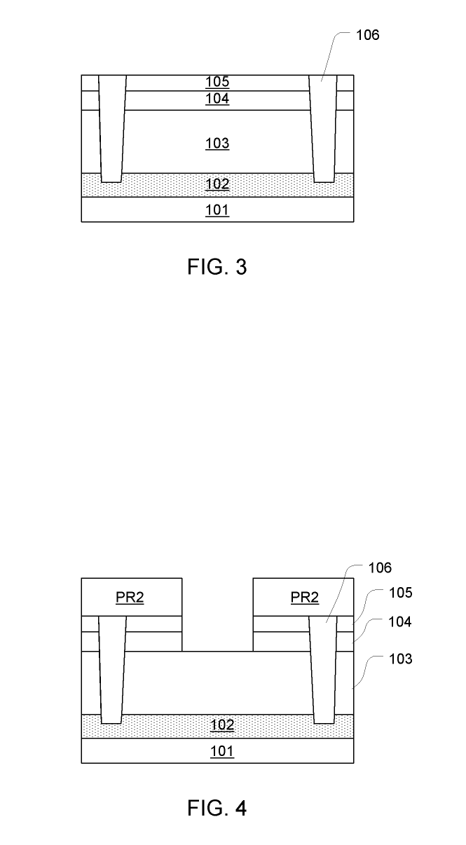

Then, an insulating material layer is formed on a surface of the semiconductor structure through known deposition processes, such as electron bean evaporation (EBM), chemical vapor deposition (CVD), atomic layer deposition (ALD), or sputtering, etc. The insulating material layer fills the shallow trenches. A portion of the insulating material layer that is outside the shallow trenches is removed by chemical mechanical polishing (CMP). A portion of the insulating material layer remaining in the shallow trench forms a shallow trench isolation 106, as shown in FIG. 3. As can be understood by those skilled in the art, the shallow trench isolation 106 defines the active region of the semiconductor device.

Then, a photoresist layer PR2 is formed on the liner nitride layer 105 by spin coating. The photoresist layer PR2 is etched by photolithography to form a gate-opening pattern, which may have a stripe shape. Exposed portions of the liner nitride layer 105 and the liner oxide layer 104 are successively removed from top to bottom with the photoresist layer PR2 as a mask through the above dry or wet etching processes, as shown in FIG. 4. The etching stops when reaching the surface of the semiconductor layer 103 and the gate-opening pattern is formed in the liner nitride layer 105 and the liner oxide layer 104. The photoresist layer PR2 is removed by dissolving in solvent or incinerating.

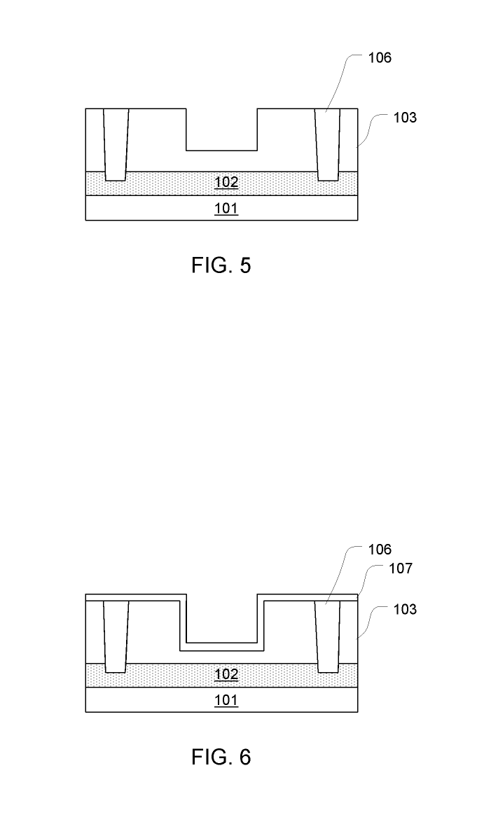

The liner nitride layer 105 and the liner oxide layer 104 are used together as a hard mask to further etch the semiconductor layer 103 to a predetermined depth by the above dry or wet etching processes, so as to form a gate opening in the semiconductor layer 103, as shown in FIG. 5. A thickness of a portion, where a channel region of a final semiconductor device is to be formed, of the semiconductor layer 103 that is underneath the gate opening may be set to a required value by controlling etching time.

As an optional step, the structure may be subjected to thermal oxidation after the gate opening is formed, such that an oxide is formed on a bottom and sidewalls of the semiconductor layer 103. Subsequently, the oxide is selectively removed with respect to the semiconductor material of the semiconductor layer 103 through the above dry or wet etching processes, in order to further reduce the thickness of the portion, where the channel region of the final semiconductor device is to be formed, of the semiconductor layer 103 underneath the gate opening.

The thickness of this portion may be reduced to about 1 nm. For example, the thickness of this portion may be controlled to be in a range of about 1 nm-30 nm. Therefore, a thickness of the channel region of the final semiconductor device may be comparative to that of the channel region provided by a conventional UTB SOI wafer. However, the cost can be substantially reduced because the UTB SOI wafer is avoided. Alternatively, the thickness of the channel region of the final semiconductor device may be substantially smaller than that of the channel region provided by the conventional UTB SOI wafer, so as to further improve the channel control.

Then, the liner nitride layer 105 is removed using, for example, heated phosphoric acid. The liner oxide layer 104 is removed using, for example, hydrofluoric acid. Then thermal oxidation is performed or silicon oxide is deposited using CVD, such that an oxide layer 107 is formed on exposed portions of the bottom and sidewalls of the gate opening and on a top surface of the semiconductor layer 103 outside the gate opening, as shown in FIG. 6. The oxide layer 107 formed in this step is used as a stop layer in a later etching step and has a thickness of about 10 nm. According to requirements for the semiconductor devices, ion implantation may be performed after the growth of the silicon oxide to adjust a threshold voltage.

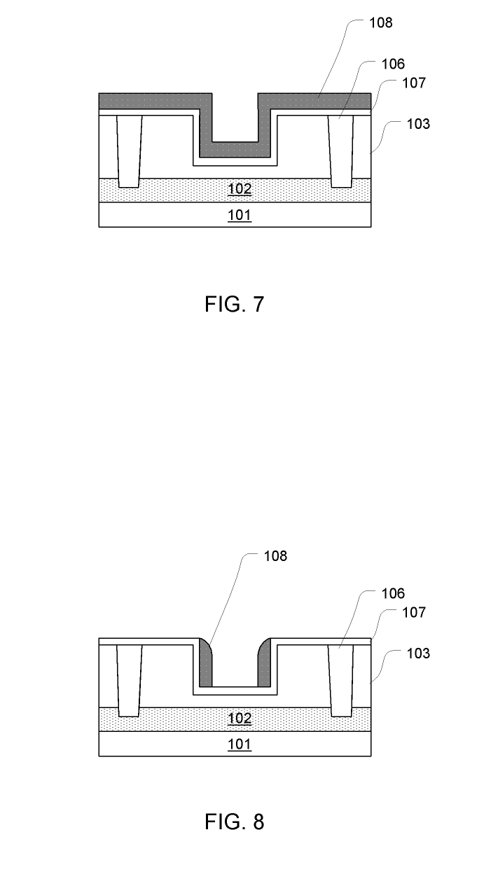

Next, a conformal nitride layer may be formed on a surface of the semiconductor structure through the above deposition process, as shown in FIG. 7.

Then, an anisotropic etching process (e.g., reactive ion etching) is performed to selectively remove, with respect to the oxide layer 107, respective portions of the nitride layer that are outside the gate opening and on the bottom of the gate opening, such that a portion of the nitride layer that is on inner sidewalls of the gate opening forms a gate spacer 108, as shown in FIG. 8. In one example, a thickness of the gate spacer 108 is determined based on the thickness of the nitride layer, such as a silicon nitride layer with a thickness of about 5 nm-50 nm. By changing the thickness of the gate sidewall 108, a required insulation capability may be achieved and a line-width for the gate may be reduced.

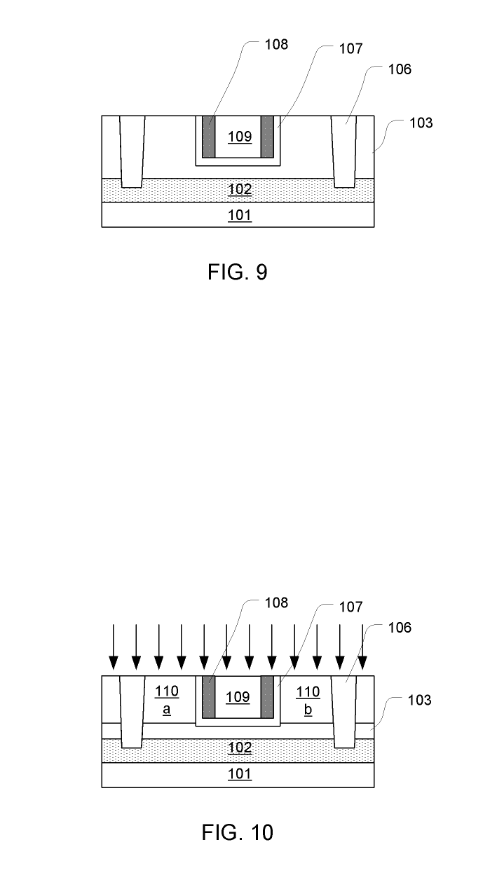

Then, an oxide layer is formed on a surface of the semiconductor structure through the above deposition process. The oxide layer fills the gate opening. The surface of the semiconductor structure is planarized using CMP. The CMP stops when reaching the top of the semiconductor layer 103, such that a portion of the oxide layer that is outside the gate opening and a protruded portion of the shallow trench isolator are removed. After the CMP, a remaining portion of the oxide layer in the gate opening becomes a sacrificial gate 109, as shown in FIG. 9. Alternatively, the sacrificial gate 109 may be made of any material that has selectivity in the etching process, instead of being limited to oxides.

In accordance with a conductive type of the final semiconductor device, an N-type or P-type dopant is used to perform ion implantation with the oxide layer 107, the gate sidewall 108, the sacrificial gate 109, and the shallow trench isolator 106 as a hard mask. Then, spike annealing or laser annealing is performed at, for example, a temperature of about 1000-1080, in order to activate the dopant implanted in the previous implantation step and eliminate damages due to the implantation. Thus, a source region 110a and a drain region 110b are formed in the semiconductor layer 103, as shown in FIG. 10.

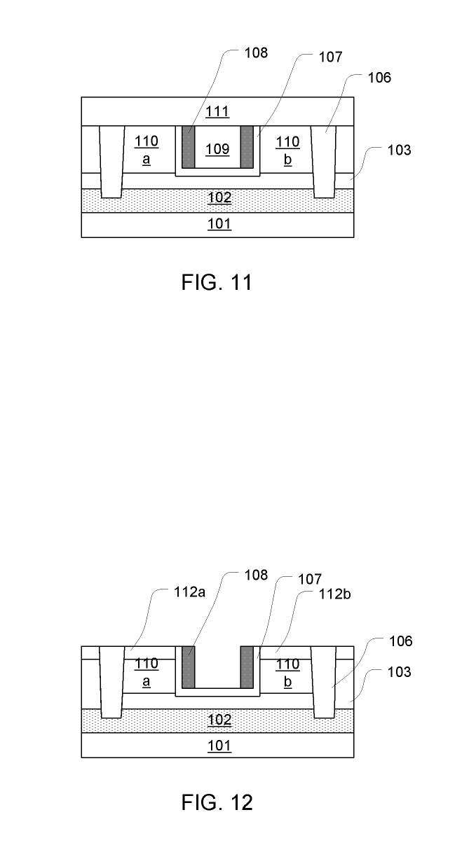

Then, as shown in FIG. 11, a metal layer 111 is formed on a surface of the semiconductor structure through the above deposition process. The metal layer 111 is made of any one of a group consisting of Ni, W, Ti, Co, and alloys constituted of any of these elements and other elements. In one example, the metal layer 111 is a NiPt layer deposited by sputtering. Thermal annealing is performed for 1-10 seconds, for example, at a temperature of about 300-500, such that the metal layer 111 is siliconized on respective surfaces of the source region 110a and the drain region 110b to form metal silicide layers 112a and 112b, to reduce contact resistance of the source region and the drain region, as shown in FIG. 11. The siliconization consumes part of the semiconductor material of the source region 110a and the drain region 110b. In the gate opening, the siliconization does not reach the portion of the semiconductor layer 103 that is underneath the gate opening, because the sacrificial gate 109 separates the metal layer 111 from the semiconductor layer 103. That is, the sacrificial gate 109 acts as a protection layer for the channel region of the semiconductor device in the siliconization process.

Then, through the above dry or wet etching processes, unreacted portions of the metal layer 111 are removed, and the sacrificial gate 109 is also removed, as shown in FIG. 12. This etching process may comprise two steps of removing the unreacted portions of the metal layer 111 and removing the sacrificial layer 109, where different etching methods and/or etchants may be used. When removing the sacrificial 109, the oxide layer 107 acts as an etching stop layer, such that the portion of the semiconductor layer 103 that is underneath the gate opening will not be over-etched. That is, the oxide layer 107 acts as a protection layer for the channel region of the semiconductor device in the etching process.

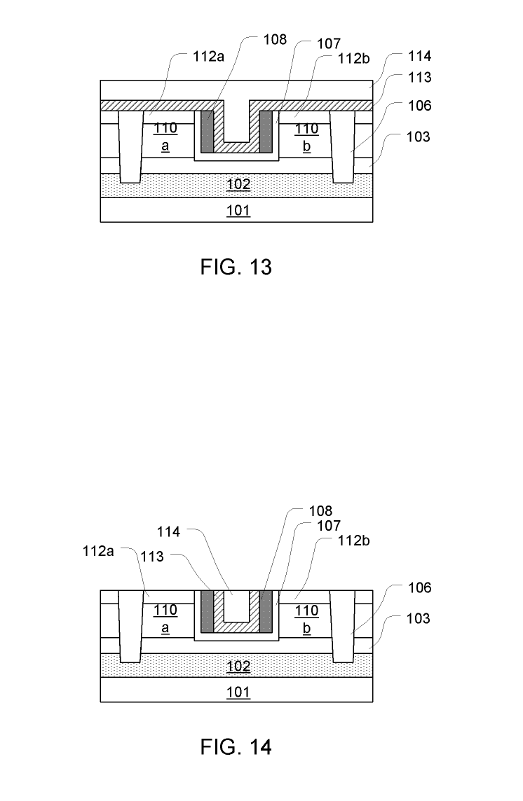

Then, through the above deposition process, a conformal replacement dielectric layer 113 is formed on a surface of the semiconductor structure, and a replacement gate conductor layer 114 is further deposited to fill the gate opening, so as to form a gate stack comprising a gate dielectric layer and a gate conductor layer, as shown in FIG. 13. For example, the replacement gate dielectric layer 113 is an HfO₂ layer with a thickness of about 1 nm-3 nm. For example, the replacement gate conductor layer 114 is a TiN layer with a thickness that is sufficient for filling the gate opening.

As an optional step, after the replacement gate dielectric 113 is formed, a threshold adjusting layer (e.g., TiN, TaN, TiAlN, and TaAlN) is formed in the gate opening, and then the replacement gate conductor layer 114 is formed. This threshold adjusting layer may adjust an effective work function, and thus adjust the threshold voltage of the semiconductor device.

Then, portions of the replacement gate dielectric layer 113 and the replacement gate conductor layer 114 that are outside the gate opening are removed through CMP, with the metal silicide layer 112a and 112b as stop layers. Portions of the replacement gate dielectric layer 113 and the replacement gate conductor layer 114 that are inside the gate opening remains to become a gate stack, as shown in FIG. 14. The CMP also exposes surfaces of the metal silicide layer 112a and 112b, to provide electric contact between plugs that are to be formed and the source region 110a and the drain region 110b.

According to this embodiment, after the steps described with respect to FIGS. 1-14, an inter-layer insulating layer, the plugs located within the inter-layer insulating layer, and wirings or electrodes located on the inter-layer insulating layer may be formed, so as to accomplish other portions of the semiconductor device.

According to the semiconductor device of the first embodiment, a top surface of the channel region is defined by the gate opening on top of a portion of the semiconductor layer 103 that provides the channel region, so as to reduce the thickness of the channel region and improve the channel control.

### Second Embodiment

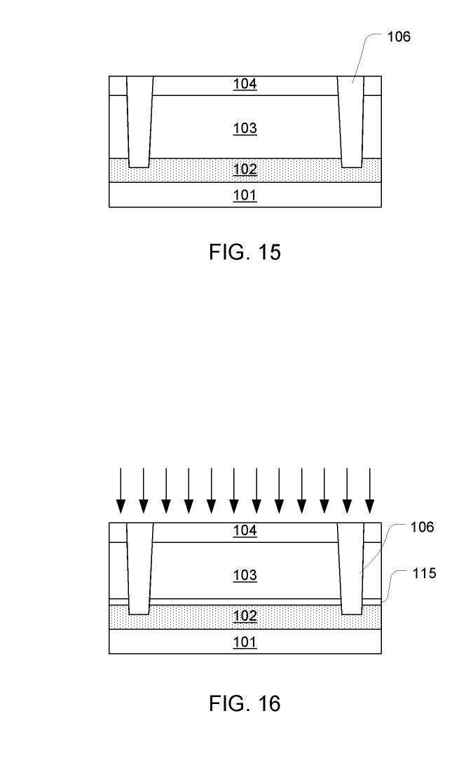

FIGS. 15-17 schematically show cross-sectional views of respective semiconductor structures at some of various stages for manufacturing a semiconductor device in accordance with a second embodiment of the method of the present disclosure, wherein each of the cross-sectional views is taken along a longitudinal direction of the channel.

According to the second embodiment of the disclosure, the thickness of the semiconductor layer 103 of the SOI wafer is further restricted using a well region. For simplicity, only differences from the first embodiments are described herein, and identical steps and corresponding structure features will not be repeated.

Steps as shown in FIGS. 15 and 16 are performed after the step of forming the shallow trench isolation 106 is performed as shown in FIG. 3 of the first embodiment.

As shown in FIG. 15, the liner nitride layer 105 is removed using heated phosphoric acid.

Then, ion implantation is performed without using a mask, such that a well region 115 is formed in the semiconductor layer 103 of the SOI wafer, as shown in FIG. 16. As is known in the art, the depth and extending range of the well region 115 may be controlled by controlling parameters for ion implantation (e.g., energy and dosage), so that the well region 115 is located at a bottom of the semiconductor layer 103. The dopant type of the well region 115 is different from that of the source region 110a and the drain region 110b of the semiconductor device. Then, steps as shown in FIG. 4-14 will be performed.

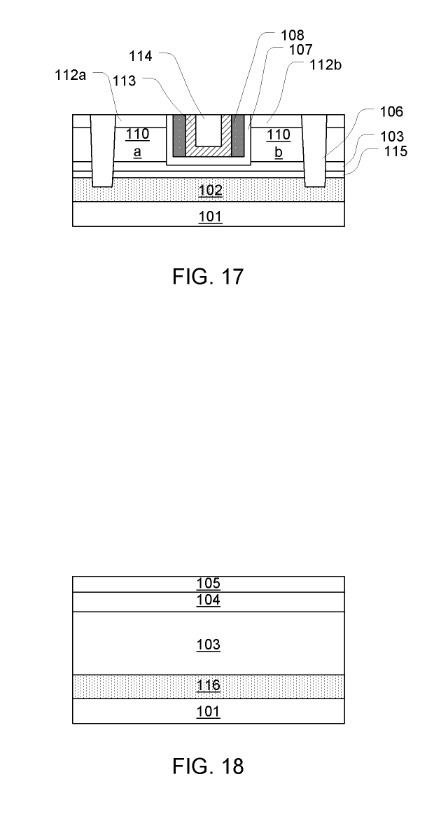

FIG. 17 shows a semiconductor structure corresponding to that in FIG. 14 of the first embodiment. According to the semiconductor device of the second embodiment, in addition to the top surface of the channel region being defined by the gate opening on the top of the portion of the semiconductor layer 103 that provides the channel region, a bottom surface of the channel region is defined by the well region 115 below the portion of the semiconductor layer 103 that provides the channel region, such that the thickness of the channel region is further reduced to improve channel control.

Additionally, because the well region 115 is below the source region 110a and the drain region 110b and is of an opposite dopant type thereof, the well region 115 also acts as a block layer reducing a leakage current between the source region 110a and the drain region 110b through the semiconductor layer 103.

### Third Embodiment

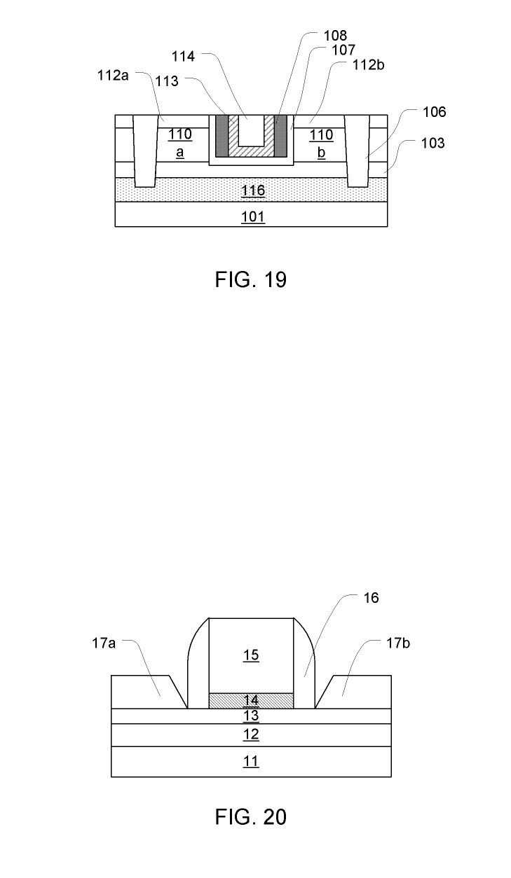

FIGS. 18-19 schematically show cross-sectional views of respective semiconductor structures at some of various stages for manufacturing a semiconductor device in accordance with a third embodiment of the method of the present disclosure, wherein each of the cross-sectional views is taken along a longitudinal direction of the channel.

According to the third embodiment of the disclosure, a bulk semiconductor substrate 101 is used instead of the expensive SOI wafer to form the semiconductor device. In the bulk semiconductor substrate 101, the well region is utilized to define the semiconductor layer and its thickness. For simplicity, only differences from the first embodiments will be described herein, and identical steps and corresponding structure features will not be repeated.

Instead of the step shown in FIG. 1 of the first embodiment, the following step as shown in FIG. 18 is executed.

The initial semiconductor structure is for example a bulk semiconductor substrate 101. A liner oxide layer 104 and a liner nitride layer 105 are successively formed on the semiconductor substrate 101. The liner oxide layer 104 is for example made of silicon oxide with a thickness of about 2 nm-20 nm. The liner nitride layer 105 is for example made of silicon nitride with a thickness of about 50 nm-200 nm. As is already known, the liner oxide layer 104 may alleviate stress between the semiconductor substrate 101 and the liner nitride layer 105. The liner nitride layer 105 is used as a hard mask in a later etching step.

Processes for forming the above layers are known. For example, the liner oxide layer 104 is formed through thermal oxidation and the liner nitride layer 105 is formed through chemical vapor deposition.

Then, ion implantation is performed without using a mask, such that a well region 116 is formed in the semiconductor substrate 101 at a predetermined depth. As is known in the art, the depth and extending range of the well region 116 may be controlled by controlling parameters for ion implantation (e.g., energy and dosage), so that the well region 116 is located at a lower portion of the semiconductor substrate 101. A portion of the semiconductor substrate 101 that is on top of the well region 116 forms the semiconductor layer 103. The dopant type of the well region 116 is different from that of the source region 110a and the drain region 110b of the semiconductor device. Then subsequent steps as shown in FIG. 2-14 will be performed.

FIG. 19 shows a semiconductor structure corresponding to that in FIG. 14 of the first embodiment. According to the semiconductor device of the third embodiment, the well region 116 is used to define the semiconductor layer 103 in the bulk semiconductor substrate 101. Therefore, in addition to the top surface of the channel region being defined by the gate opening on top of the portion of the semiconductor layer 103 that provides the channel region, a bottom surface of the channel region is defined by the well region 116 below the portion of the semiconductor layer 103 that provides the channel region, such that the thickness of the channel region is further reduced to improve the channel control. Moreover, the manufacturing cost is reduced as SOI wafer is not required anymore.

Additionally, because the well region 116 is below the source region 110a and the drain region 110b and is of an opposite dopant type thereof, the well region 116 also acts as a block layer reducing a leakage current between the source region 110a and the drain region 110b through the semiconductor layer 103.

In the above description, technical details regarding some aspects, such as patterning or etching, of the layers are not specifically illustrated. However, those skilled in the art should understand that, layers or regions of required shape may be formed via various technical manners. Additionally, those skilled in the art may also design other methods that are not identical to the method described above in order to form an identical structure. Although the embodiments are described as above, it does not mean that the measures in these embodiments cannot be combined to achieve additional advantages.

What is claimed is:

1. A method for manufacturing a semiconductor device, comprising:
forming a gate opening in a semiconductor layer;
forming a sacrificial gate in the gate opening;
forming a source region and a drain region in the semiconductor layer in proximity to the gate opening;
removing the sacrificial gate; and
forming a gate stack comprising a replacement gate dielectric layer and a replacement gate conductor layer in the gate opening,
wherein the gate opening is configured to define a thickness of a portion of the semiconductor layer for a channel region.

2. The method according to claim 1, wherein the gate opening is configured to define a top surface of the portion of the semiconductor layer for the channel region.

3. The method according to claim 1, further comprising, before forming the gate opening:
further reducing the thickness of the portion of the semiconductor layer for the channel region.

4. The method according to claim 3, wherein said further reducing the thickness of the portion of the semiconductor layer for the channel region comprising:
performing ion implantation in the semiconductor layer to form a well region at a bottom of the semiconductor layer, wherein the well region has a dopant type opposite to that of the source region and the drain region.

5. The method according to claim 4, wherein the well region is configured to define a bottom surface of the portion of the semiconductor layer for the channel region.

6. The method according to claim 1, further comprising, after forming the gate opening and before forming the sacrificial gate:
further reducing the thickness of the portion of the semiconductor layer for the channel region.

7. The method according to claim 6, wherein said further reducing the thickness of the portion of the semiconductor layer for the channel region comprising:
performing thermal oxidation to form an oxide layer on exposed portions of the semiconductor layer on a bottom and sidewalls of the gate opening; and
removing the oxide layer with respect to the semiconductor layer.

8. The method according to claim 1, further comprising, after forming the gate opening and before forming the sacrificial gate:
forming a gate spacer on inner sidewalls of the gate opening.

9. The method according to claim 1, wherein:
the semiconductor layer is a semiconductor layer of an SOI wafer; and
the SOI wafer further comprises:
a semiconductor substrate; and
a buried insulating layer between the semiconductor substrate and the semiconductor layer.

10. The method according to claim 1, further comprising, before forming the gate opening:
performing ion implantation in a bulk semiconductor substrate to form a well region, such that a portion of the semiconductor substrate above the well region forms the semiconductor layer, wherein the well region has a dopant type opposite to that of the source region and the drain region.

11. The method according to claim 1, further comprising, after forming the gate opening and before forming the sacrificial gate:
performing ion implantation in the semiconductor layer via the gate opening to adjust a threshold voltage.

12. A semiconductor device, comprising:
a gate opening in a semiconductor layer;
a gate stack comprising a replacement gate dielectric layer and a replacement gate conductor layer in the gate opening; and
a source region and a drain region in the semiconductor layer in proximity to the gate opening,
wherein the gate opening is configured to define a thickness of a portion of the semiconductor layer for a channel region.

13. A semiconductor device according to claim 12, wherein the gate opening is configured to define a top surface of the portion of the semiconductor layer for the channel region.

14. A semiconductor device according to claim 12, further comprising a well region at a bottom of the semiconductor layer, the well region being configured to define a bottom surface of the portion of the semiconductor layer for the channel region, wherein the well region has a dopant type opposite to that of the source region and the drain region.

15. A semiconductor device according to claim 12, wherein the thickness of the portion of the semiconductor layer for the channel region is between 1 nm and 30 nm.

16. A semiconductor device according to claim 12, further comprising a gate spacer in the gate opening.

17. A semiconductor device according to claim 12, wherein the semiconductor layer is a semiconductor layer of an SOI wafer,

18. A semiconductor device according to claim 12, wherein the semiconductor layer is a portion of a bulk semiconductor substrate above a well region, wherein the well region has a dopant type opposite to that of the source region and the drain region.
